(19) United States
(12) Patent Application Publication
(10) Pub. No.: US 2006/0204783 A1
(43) Pub. Date: Sep. 14, 2006

(54) Organic electroluminescent device

(76) Inventors: Scott R. Conley, Rochester, NY (US); Michele L. Ricks, Rochester, NY (US); William J. Begley, Webster, NY (US); Daniel J. Gisser, Pittsford, NY (US)

Correspondence Address: Paul A. Leipold;Patent Legal Staff, Eastman Kodak Company, 343 State Street, Rochester, NY, 14650-2201, US

(21) Appl. No.: 11/076,720

(22) Filed: Mar. 10, 2005

(51) Int. Cl. H01L 51/54; H05B 33/14

(52) U.S. Cl. 428/690; 428/917; 313/504; 313/506; 257/102; 257/103; 257/E51.049; 257/E51.05

(57) ABSTRACT

An OLED device comprises a cathode, an anode, and having therebetween a light emitting layer containing
(a) an anthracene material represented by Formula (1): 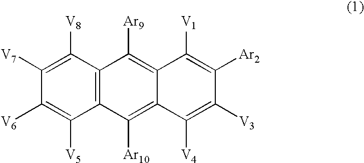 wherein:
Ar₂, Ar₉, and Ar₁₀ independently represent an aryl group,
v₁, v₃, v₄, v₅, v₆, v₇, and v₈ independently represent hydrogen or a substituent; and (b) a light emitting dopant;
   the device further containing on the cathode side of the light emitting layer an electron transporting layer that contains a minor portion or no AlQ₃. The device exhibits improved color or operating voltage or both.

### FIELD OF INVENTION

This invention relates to organic electroluminescent (EL) devices. More specifically, this invention relates to blue electroluminescent devices comprising an electron transport layer containing no more than a minor portion of AlQ₃.

### BACKGROUND OF THE INVENTION

While organic electroluminescent (EL) devices have been known for over two decades, their performance limitations have represented a barrier to many desirable applications. In simplest form, an organic EL device is comprised of an anode for hole injection, a cathode for electron injection, and an organic medium sandwiched between these electrodes to support charge recombination that yields emission of light. These devices are also commonly referred to as organic light-emitting diodes, or OLEDs. Representative of earlier organic EL devices are Gurnee et al. U.S. Pat. No. 3,172,862, issued Mar. 9, 1965; Gurnee U.S. Pat. No. 3,173,050, issued Mar. 9, 1965; Dresner, “Double Injection Electroluminescence in Anthracene”, RCA Review, Vol. 30, pp. 322-334, 1969; and Dresner U.S. Pat. No. 3,710,167, issued Jan. 9, 1973. The organic layers in these devices, usually composed of a polycyclic aromatic hydrocarbon, were very thick (much greater than 1 μm). Consequently, operating voltages were very high, often >100V.

More recent organic EL devices include an organic EL element consisting of extremely thin layers (e.g. <1.0 μm) between the anode and the cathode. Herein, the term “organic EL element” encompasses the layers between the anode and cathode electrodes. Reducing the thickness lowered the resistance of the organic layer and has enabled devices that operate much lower voltage. In a basic two-layer EL device structure, described first in U.S. Pat. No. 4,356,429, one organic layer of the EL element adjacent to the anode is specifically chosen to transport holes, therefore, it is referred to as the hole-transporting layer, and the other organic layer is specifically chosen to transport electrons, referred to as the electron-transporting layer. Recombination of the injected holes and electrons within the organic EL element results in efficient electroluminescence.

There have also been proposed three-layer organic EL devices that contain an organic light-emitting layer (LEL) between the hole-transporting layer and electron-transporting layer, such as that disclosed by Tang et al [J. Applied Physics, Vol. 65, Pages 3610-3616, 1989]. The light-emitting layer commonly consists of a host material doped with a guest material. Still further, there has been proposed in U.S. Pat. No. 4,769,292 a four-layer EL element comprising a hole-injecting layer (HIL), a hole-transporting layer (HTL), a light-emitting layer (LEL) and an electron transport/injection layer (ETL). These structures have resulted in improved device efficiency.

Since these early inventions, further improvements in device materials have resulted in improved performance in attributes such as color, stability, luminance efficiency and manufacturability, e.g., as disclosed in U.S. Pat. No. 6,465,115 and U.S. Pat. No. 6,661,023 amongst others.

A useful class of host materials are anthracenes, their use has been disclosed in U.S. Pat. No. 5,935,721, U.S. Pat. No. 6,465,115, JP2004059535, and others. Various electron transporting materials are useful for OLED devices, such as tris(8-quinolinolato)aluminum (III) (AlQ₃), bis(2-methyl-8-quinolinolato)(4-phenylphenolato)aluminum(III) (BAlq), and benzazoles; as disclosed in U.S. Pat. No. 4,885,211, U.S. Pat. No. 5,141,671, and WO2003060956.

Anthracenes may also function as hole transporting materials as disclosed in U.S. Pat. No. 6,465,115. This hole transporting characteristic of anthracenes may be exhibited when an anthracene is used as the host material resulting in the recombination and light emission occurring in the electron transporting layer instead of the light emitting layer. When light is emitted from the electron transporting layer it is often not the desired color, as disclosed in 5th International Conference on Electroluminescence of Molecular Materials and Related Phenomena, Low Voltage Organic Light Emitting Devices (OLEDs) Using a Triazine Electron Transport Layer, January 2005. This undesirable effect is enhanced when a dopant is not used in the light emitting layer, as shown in U.S. Pat. No. 4,769,292.

A desirable blue color is one in which there is less green emission. Blue emission that is contaminated with green emission lowers the color gamut of the display.

The inventors have found that OLED devices made with 2,9,10-triaryl substituted anthracenes as the host often have an emission that is too green. It is a problem to be solved to provide 2,9,10-triaryl substituted anthracene host materials and electron transporting materials for use in an OLED device that exhibit an improved emission color or reduced operating voltage or both.

### SUMMARY OF THE INVENTION

OLED device comprises a cathode, an anode, and having therebetween a light emitting layer containing
(a) an anthracene material represented by Formula (1): 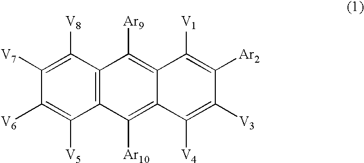
   wherein:
   Ar₂, Ar₉, and Ar₁₀ independently represent an aryl group,
   v₁, v₃, v₄, v₅, v₆, v₇, and v₈ independently represent hydrogen or a substituent; and
(b) a light emitting dopant;
   the device further containing on the cathode side of the light emitting layer an electron transporting layer that contains a minor portion or no AlQ₃.

The device exhibits improved color or operating voltage or both.

### BRIEF DESCRIPTION OF THE DRAWINGS

FIG. 1 shows a schematic cross-section of a typical OLED device (not to scale) in which this invention may be used.

### DETAILED DESCRIPTION OF THE INVENTION

The invention is generally summarized above.

As used herein, the term “minor portion” with respect to AlQ₃ means there is less than 30 vol % of AlQ₃ in the layer. Desirably, even lesser amounts are employed. The ETL may be adjacent to the light emitting layer or separated from it. It may be desirable for the electron transporting layer to be substantially free of any material capable of emitting green light when in an emitting layer.

The anthracene host material may be a 2-aryl, 9,10-dinaphthalene anthracene. Some non-limiting examples of anthracene compounds useful as host materials are represented by:

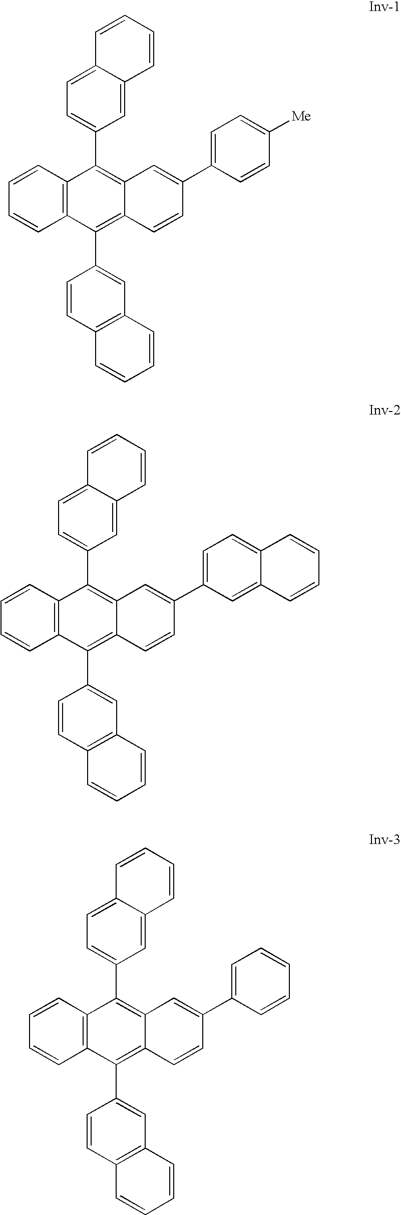

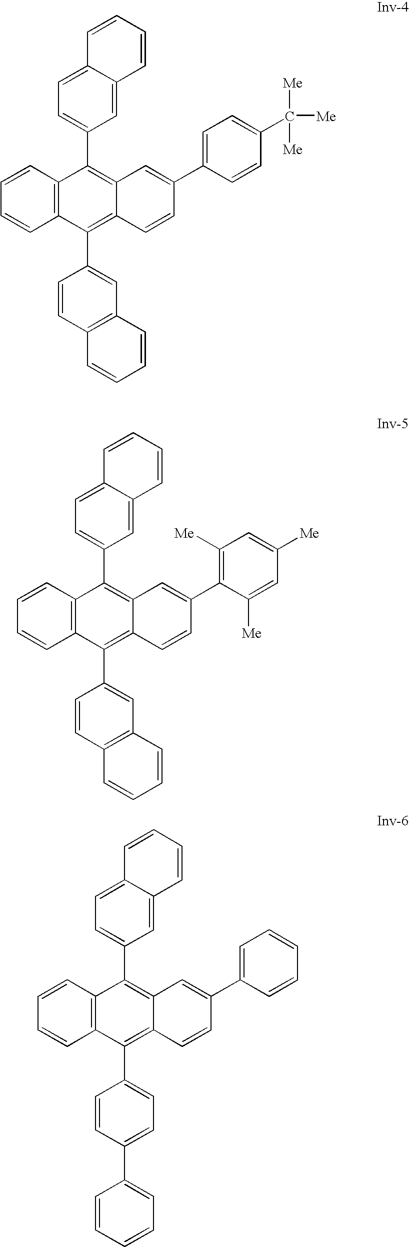

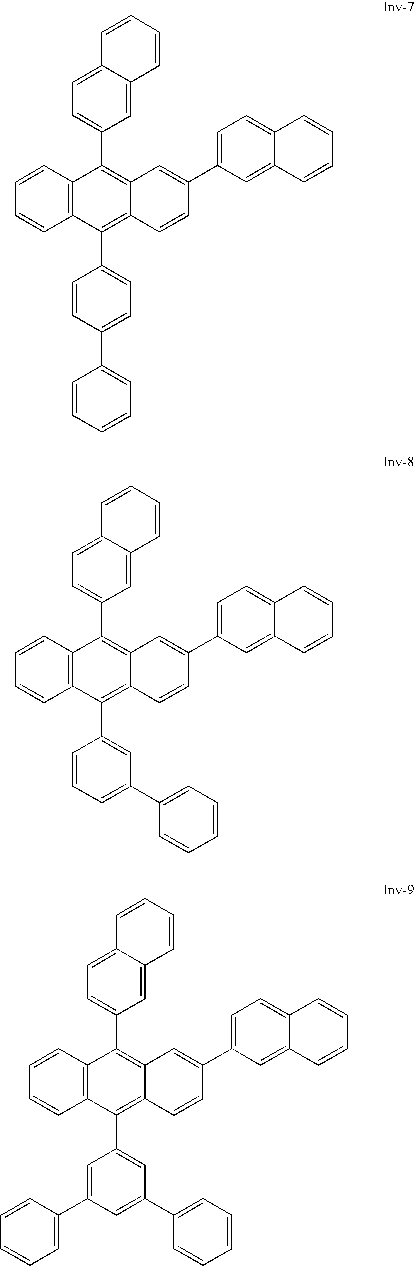

The light emitting dopant may be represented by Formula (2): 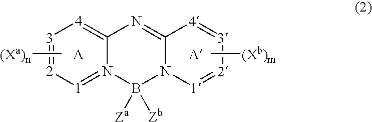
wherein

A and A′ represent independent azine ring systems corresponding to 6-membered aromatic ring systems containing at least one nitrogen;

each X^{a} and X^{b} is an independently selected substituent, two of which may join to form a fused ring to A or A′;

m and n are independently 0 to 4;

Z^{a} and Z^{b} are independently selected substituents; and

1, 2, 3, 4, 1′, 2′, 3′, and 4′ are independently selected as either carbon or nitrogen atoms.

A material comprising the electron transporting layer may be represented by Formula (3), 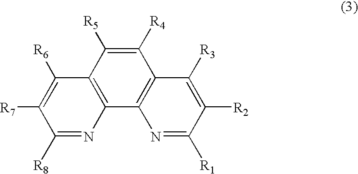
wherein:

R₁-R₈ are independently hydrogen, alkyl, aryl or substituted aryl, and at least one of R₁-R₈ is aryl or substituted aryl. Suitable the electron transporting material may comprises 2 phenanthroline ring groups. Desirably, the electron transporting material may be selected from the group consisting of: 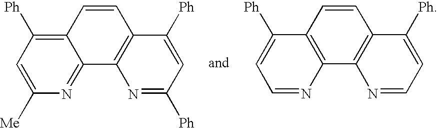
The electron transporting layer may also comprise lithium.

A material comprising the electron transporting layer may be represented by Formula (4), 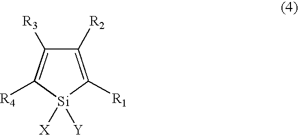
wherein:

R₁ to R₄ are independently hydrogen, alkyl, aryl, or heteroaryl groups;

X and Y are independently hydrogen, alkyl, aryl, or heteroaryl groups, and may be bonded together to form a saturated or unsaturated ring. Suitably, both R₁ and R₄ comprise a 5 or 6 membered ring containing a nitrogen atom.

A material comprising the electron transporting layer may be represented by Formula (6), 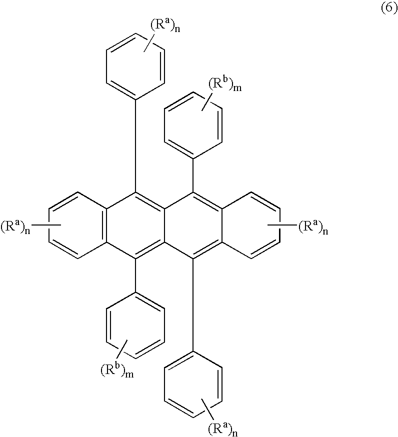
wherein:

R^{a} and R^{b} are substituent groups;

n is selected from 0-4; and

m is selected from 0-5.

Desirably, the material comprising the electron transporting layer is represented by Formula (7) or (8), 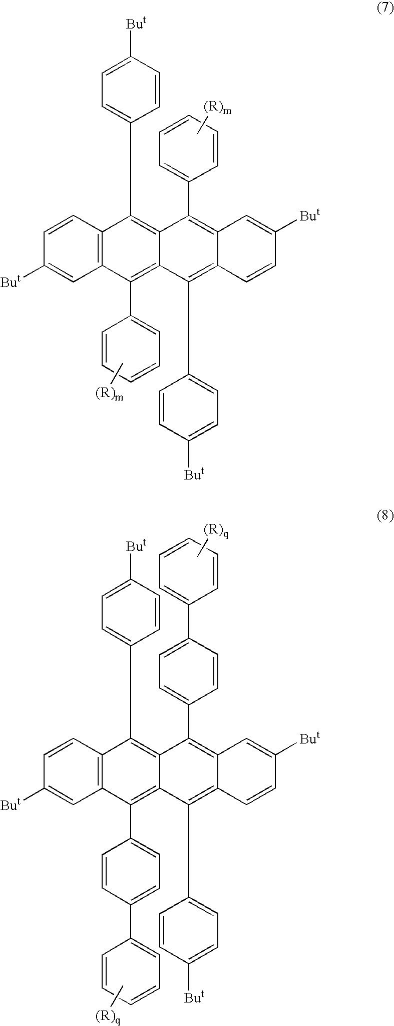
wherein:

R are substituent groups;

m is selected from 0-5; and

q is selected from 0-5.

Another material comprising the electron transporting layer may be represented by Formula (12), 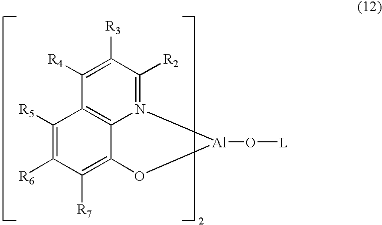
wherein:
R₂ represents an electron donating group,
R₃ and R₄ each independently represent hydrogen or an electron donating group,
R₅, R₆, and R₇ each independently represent hydrogen or an electron accepting group, and
L is an aromatic moiety linked to the aluminum by oxygen which may be substituted such that L has from 7 to 24 carbon atoms.

Another embodiment of the invention comprises an OLED device comprising a cathode, an anode, and having therebetween a light emitting layer containing an 2,9,10-triaryl substituted anthracene compound and containing on the cathode side of the light emitting layer an electron transporting layer that comprises one or more compounds selected from: 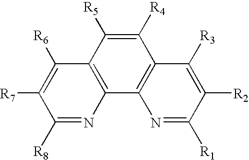
wherein:

R₁-R₈ are independently hydrogen, alkyl, aryl or substituted aryl, and at least one of R₁-R₈ is aryl or substituted aryl; or 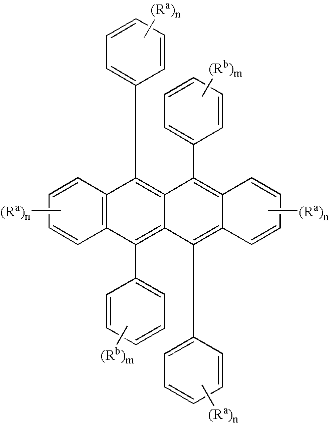
wherein:

R^{a} and R^{b} are substituent groups;

n is selected from 0-4; and

m is selected from 0-5.

The anthracene host material may be represented by Formula (14), 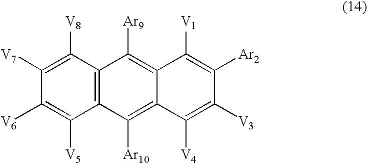
wherein:
Ar₂ represent an aryl group,
Ar₉, and Ar₁₀ independently represent a naphthalene group, and
v₁, v₃, v₄, v₅, v₆, v₇, and v₈ independently represent hydrogen or a substituent.

Suitably, the electron transporting material may be selected from the group consisting of: 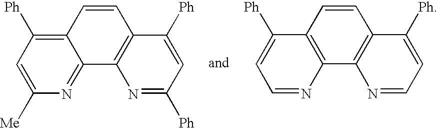
The electron transporting layer may also comprise lithium.

Desirably, the material comprising the electron transporting layer is selected from a group consisting of Formula (15) and (16), 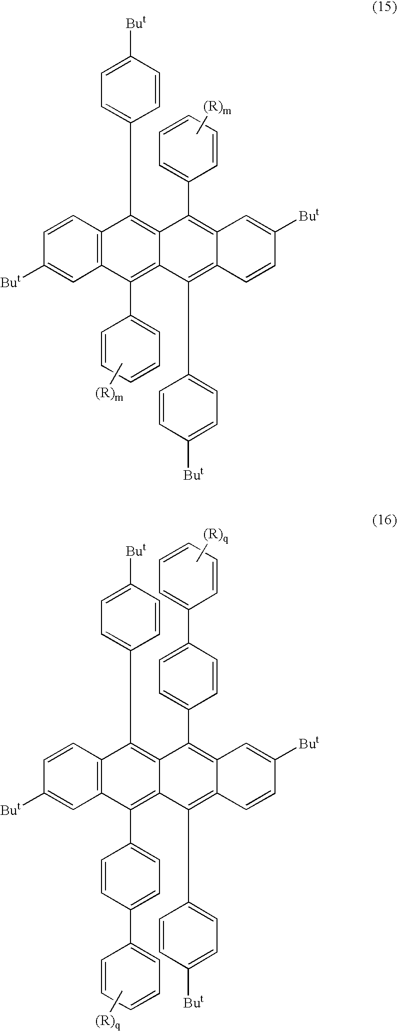
wherein:

R are substituent groups;

m is selected from 0-5; and

q is selected from 0-5.

Some non-limiting examples of electron transporting materials useful in the embodiment of the invention are listed below:

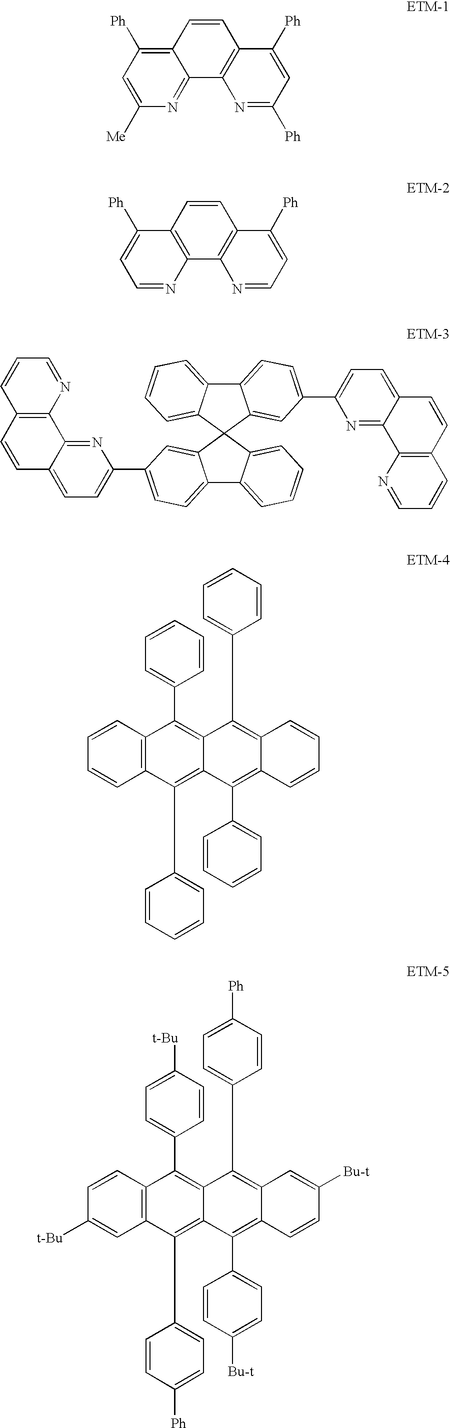

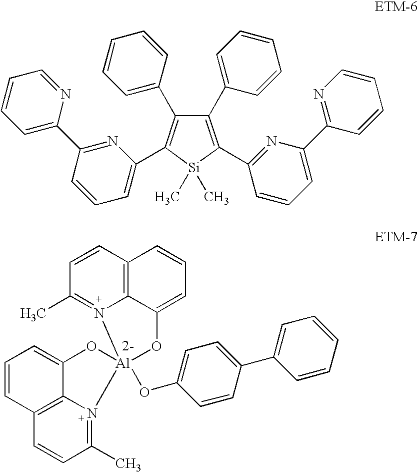

In some cases it is desirable to dope lithium into the electron transporting layer up to 5% by volume to improve the emission color.

Suitably, the anthracene material comprises the host material, and there may be more than one host materials. The light-emitting material(s) is present in an amount of up to 15 vol. % of the host, commonly 0.1-10 vol. % and more typically from 0.1-5.0 vol. % of the host.

Unless otherwise specifically stated, use of the term “substituted” or “substituent” means any group or atom other than hydrogen. Unless otherwise provided, when a group (including a compound or complex) containing a substitutable hydrogen is referred to, it is also intended to encompass not only the unsubstituted form, but also form further substituted with any substituent group or groups as herein mentioned, so long as the substituent does not destroy properties necessary for utility. Suitably, a substituent group may be halogen or may be bonded to the remainder of the molecule by an atom of carbon, silicon, oxygen, nitrogen, phosphorous, sulfur, selenium, or boron. The substituent may be, for example, halogen, such as chloro, bromo or fluoro; nitro; hydroxyl; cyano; carboxyl; or groups which may be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonylamino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropylsulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which may be substituted and which contain a 3 to 7 membered heterocyclic ring composed of carbon atoms and at least one hetero atom selected from the group consisting of oxygen, nitrogen, sulfur, phosphorous, or boron. such as 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents may themselves be further substituted one or more times with the described substituent groups. The particular substituents used may be selected by those skilled in the art to attain the desired desirable properties for a specific application and can include, for example, electron-withdrawing groups, electron-donating groups, and steric groups. When a molecule may have two or more substituents, the substituents may be joined together to form a ring such as a fused ring unless otherwise provided. Generally, the above groups and substituents thereof may include those having up to 48 carbon atoms, typically 1 to 36 carbon atoms and usually less than 24 carbon atoms, but greater numbers are possible depending on the particular substituents selected.

General Device Architecture

The present invention can be employed in most OLED device configurations. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

There are numerous configurations of the organic layers wherein the present invention can be successfully practiced. The essential requirements of an OLED are an anode, a cathode, and an organic light-emitting layer located between the anode and cathode. Additional layers may be employed as more fully described hereafter.

Anode

When the desired electroluminescent light emission (EL) is viewed through anode, the anode should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is viewed only through the cathode, the transmissive characteristics of the anode are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize shorts or enhance reflectivity.

Cathode

When light emission is viewed solely through the anode, the cathode used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One useful cathode material is comprised of a Mg:Ag alloy wherein the percentage of silver is in the range of 1 to 20%, as described in U.S. Pat. No. 4,885,221. Another suitable class of cathode materials includes bilayers comprising the cathode and a thin electron-injection layer (EIL) in contact with an organic layer (e.g., an electron transporting layer (ETL)) which is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861; 5,059,862, and 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, U.S. Pat. No. 6,278,236, and U.S. Pat. No. 6,284,3936. Cathode materials are typically deposited by any suitable method such as evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Light-Emitting Layer (LEL)

As more fully described in U.S. Pat. Nos. 4,769,292 and 5,935,721, the light-emitting layer (LEL) of the organic EL element includes a luminescent fluorescent or phosphorescent material where electroluminescence is produced as a result of electron-hole pair recombination in this region. The light-emitting layer can be comprised of a single material, but more commonly consists of a host material doped with a guest emitting material or materials where light emission comes primarily from the emitting materials and can be of any color. The host materials in the light-emitting layer can be an electron-transporting material, as defined below, a hole-transporting material, as defined above, or another material or combination of materials that support hole-electron recombination. The emitting material is usually chosen from highly fluorescent dyes and phosphorescent compounds, e.g., transition metal complexes as described in WO 98/55561, WO 00/18851, WO 00/57676, and WO 00/70655. Emitting materials are typically incorporated at 0.01 to 10% by weight of the host material.

The host and emitting materials can be small non-polymeric molecules or polymeric materials such as polyfluorenes and polyvinylarylenes (e.g., poly(p-phenylenevinylene), PPV). In the case of polymers, small molecule emitting materials can be molecularly dispersed into a polymeric host, or the emitting materials can be added by copolymerizing a minor constituent into a host polymer.

An important relationship for choosing an emitting material is a comparison of the bandgap potential which is defined as the energy difference between the highest occupied molecular orbital and the lowest unoccupied molecular orbital of the molecule. For efficient energy transfer from the host to the emitting material, a necessary condition is that the band gap of the dopant is smaller than that of the host material. For phosphorescent emitters it is also important that the host triplet energy level of the host be high enough to enable energy transfer from host to emitting material.

Host and emitting materials known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, and U.S. Pat. No. 6,020,078.

Derivatives of 9,10-di-(2-naphthyl)anthracene (Formula F) constitute one class of useful host materials capable of supporting electroluminescence, and are particularly suitable for light emission of wavelengths longer than 400 nm, e.g., blue, green, yellow, orange or red. 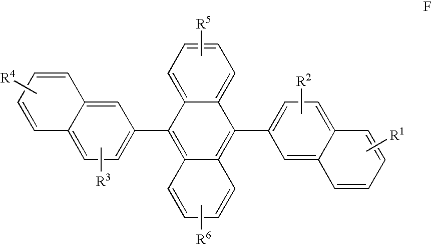
wherein: R¹, R₂, R₃, R₄, R₅, and R⁶ represent one or more substituents on each ring where each substituent is individually selected from the following groups:

Group 1: hydrogen, or alkyl of from 1 to 24 carbon atoms;

Group 2: aryl or substituted aryl of from 5 to 20 carbon atoms;

Group 3: carbon atoms from 4 to 24 necessary to complete a fused aromatic ring of anthracenyl; pyrenyl, or perylenyl;

Group 4: heteroaryl or substituted heteroaryl of from 5 to 24 carbon atoms as necessary to complete a fused heteroaromatic ring of furyl, thienyl, pyridyl, quinolinyl or other heterocyclic systems;

Group 5: alkoxylamino, alkylamino, or arylamino of from 1 to 24 carbon atoms; and

Group 6: fluorine, chlorine, bromine or cyano.

Illustrative examples include 9,10-di-(2-naphthyl)anthracene and 2-t-butyl-9,10-di-(2-naphthyl)anthracene. Other anthracene derivatives can be useful as a host in the LEL, including derivatives of 9,10-bis[4-(2,2-diphenylethenyl)phenyl]anthracene.

Useful fluorescent emitting materials include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl)methane compounds, and carbostyryl compounds. Illustrative examples of useful materials include, but are not limited to, the following:

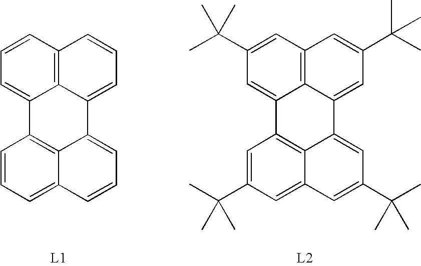

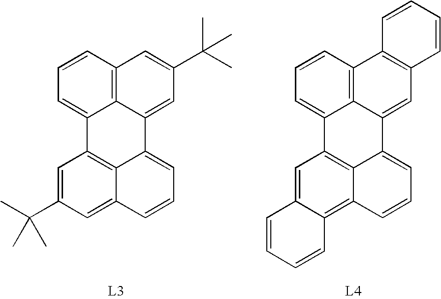

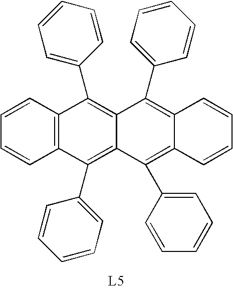

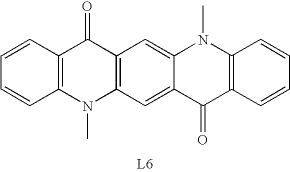

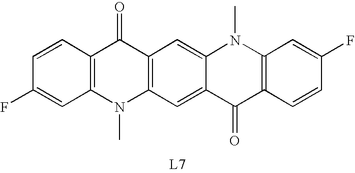

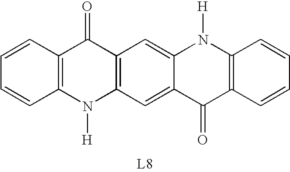

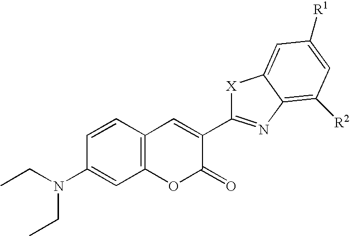

| | X | R1 | R2 |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl |

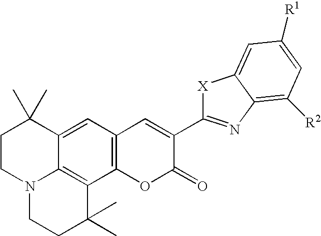

| | X | R1 | R2 |
|---|---|---|---|
| L23 | O | H | H |
| L24 | O | H | Methyl |
| L25 | O | Methyl | H |
| L26 | O | Methyl | Methyl |
| L27 | O | H | t-butyl |
| L28 | O | t-butyl | H |
| L29 | O | t-butyl | t-butyl |
| L30 | S | H | H |
| L31 | S | H | Methyl |
| L32 | S | Methyl | H |
| L33 | S | Methyl | Methyl |
| L34 | S | H | t-butyl |
| L35 | S | t-butyl | H |
| L36 | S | t-butyl | t-butyl |

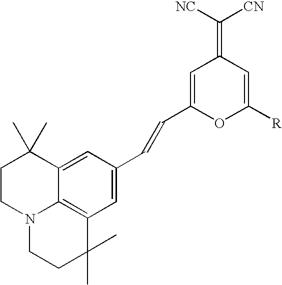

| | R |
|---|---|
| L37 | phenyl |
| L38 | methyl |
| L39 | t-butyl |
| L40 | mesityl |

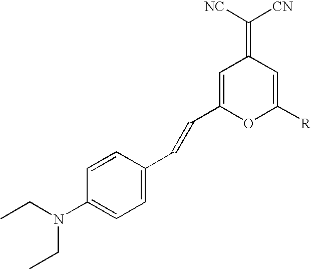

| | R |
|---|---|
| L41 | phenyl |
| L42 | methyl |
| L43 | t-butyl |
| L44 | mesityl |

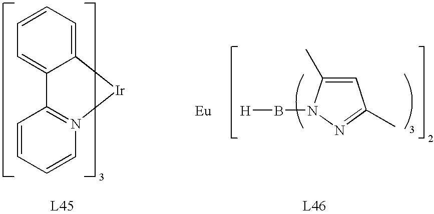

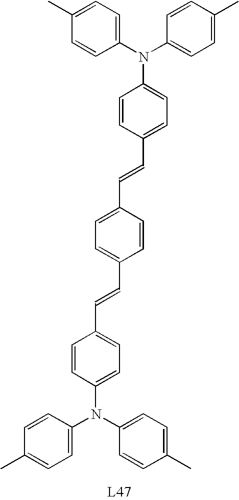

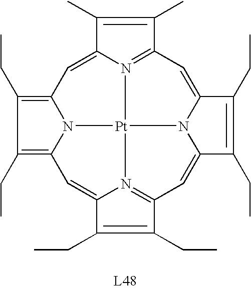

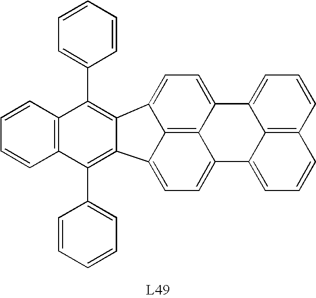

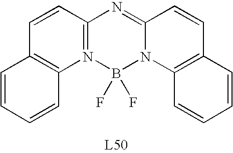

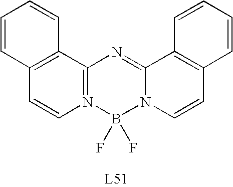

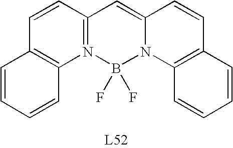

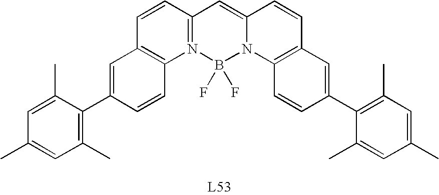

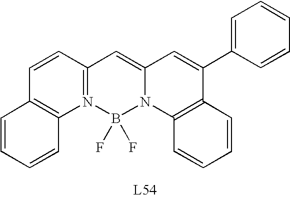

Device

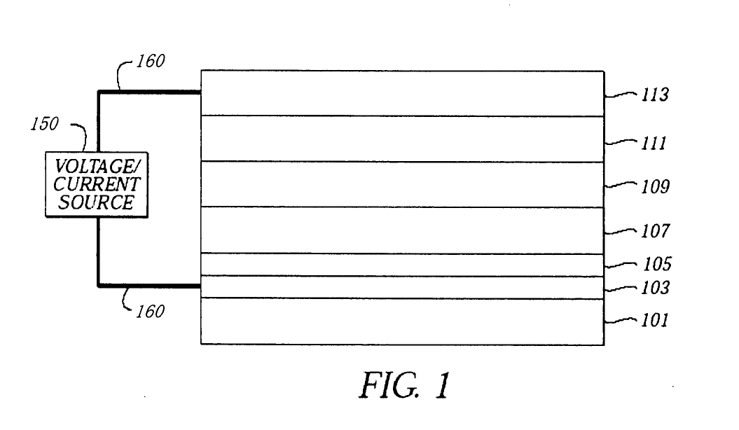

A typical structure, especially useful for of a small molecule device, is shown in FIG. 1 and is comprised of a substrate 101, an anode 103, a hole-injecting layer 105, a hole-transporting layer 107, a light-emitting layer 109, an electron-transporting layer 111, and a cathode 113. These layers are described in detail below. Note that the substrate may alternatively be located adjacent to the cathode, or the substrate may actually constitute the anode or cathode. The organic layers between the anode and cathode are conveniently referred to as the organic EL element. Also, the total combined thickness of the organic layers is preferably less than 500 nm.

The anode and cathode of the OLED are connected to a voltage/current source 250 through electrical conductors 260. The OLED is operated by applying a potential between the anode and cathode such that the anode is at a more positive potential than the cathode. Holes are injected into the organic EL element from the anode and electrons are injected into the organic EL element at the anode. Enhanced device stability can sometimes be achieved when the OLED is operated in an AC mode where, for some time period in the cycle, the potential bias is reversed and no current flows. An example of an AC driven OLED is described in U.S. Pat. No. 5,552,678.

Substrate

The OLED device of this invention is typically provided over a supporting substrate 101 where either the cathode or anode can be in contact with the substrate. The electrode in contact with the substrate is conveniently referred to as the bottom electrode. Conventionally, the bottom electrode is the anode, but this invention is not limited to that configuration. The substrate can either be light transmissive or opaque, depending on the intended direction of light emission. The light transmissive property is desirable for viewing the EL emission through the substrate. Transparent glass or plastic is commonly employed in such cases. The substrate may be a complex structure comprising multiple layers of materials. This is typically the case for active matrix substrates wherein TFTs are provided below the OLED layers. It is still necessary that the substrate, at least in the emissive pixilated areas, be comprised of largely transparent materials such as glass or polymers. For applications where the EL emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, silicon, ceramics, and circuit board materials. Again, the substrate may be a complex structure comprising multiple layers of materials such as found in active matrix TFT designs. Of course it is necessary to provide in these device configurations a light-transparent top electrode.

Hole-Injecting Layer (HIL)

While not always necessary, it is often useful that a hole-injecting layer 105 be provided between anode 103 and hole-transporting layer 107. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, plasma-deposited fluorocarbon polymers as described in U.S. Pat. No. 6,208,075, and some aromatic amines, for example, m-MTDATA (4,4′,4″-tris[(3-methylphenyl)phenylamino]triphenylamine). Alternative hole-injecting materials reportedly useful in organic EL devices are described in EP 0 891 121 A1 and EP 1 029 909 A1. Aromatic tertiary amines discussed below may also be useful as hole-injecting materials. Other useful hole-injecting materials such as Dipyrazino[2,3-f:2′,3′-h]quinoxalinehexacarbonitrile are described in US 2004113547 and U.S. Pat. No. 6,720,573.

Hole-Transporting Layer (HTL)

The hole-transporting layer 107 of the organic EL device contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pat. No. 3,658,520.

A more preferred class of aromatic tertiary amines are those which include at least two aromatic tertiary amine moieties as described in U.S. Pat. No. 4,720,432 and U.S. Pat. No. 5,061,569. Such compounds include those represented by structural formula (A). 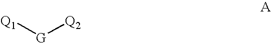
wherein Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural formula (A) and containing two triarylamine moieties is represented by structural formula (B): 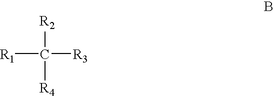
where

R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural formula (C): 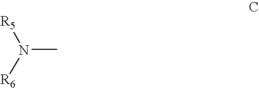
wherein R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by formula (C), linked through an arylene group. Useful tetraaryldiamines include those represented by formula (D). 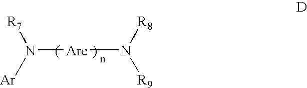
wherein
each Are is an independently selected arylene group, such as a phenylene or anthracene moiety,
n is an integer of from 1 to 4, and
Ar, R₇, R₈, and R₉ are independently selected aryl groups.
In a typical embodiment, at least one of Ar, R₇, R₈, and R₉ is a polycyclic fused ring structure, e.g., a naphthalene

The various alkyl, alkylene, aryl, and arylene moieties of the foregoing structural formulae (A), (B), (C), (D), can each in turn be substituted. Typical substituents include alkyl groups, alkoxy groups, aryl groups, aryloxy groups, and halogen such as fluoride, chloride, and bromide. The various alkyl and alkylene moieties typically contain from about 1 to 6 carbon atoms. The cycloalkyl moieties can contain from 3 to about 10 carbon atoms, but typically contain five, six, or seven ring carbon atoms—e.g., cyclopentyl, cyclohexyl, and cycloheptyl ring structures. The aryl and arylene moieties are usually phenyl and phenylene moieties.

The hole-transporting layer can be formed of a single or a mixture of aromatic tertiary amine compounds. Specifically, one may employ a triarylamine, such as a triarylamine satisfying the formula (B), in combination with a tetraaryldiamine, such as indicated by formula (D). When a triarylamine is employed in combination with a tetraaryldiamine, the latter is positioned as a layer interposed between the triarylamine and the electron injecting and transporting layer. Aromatic tertiary amines are useful as hole injection materials also. Illustrative of useful aromatic tertiary amines are the following:
1,1-Bis(4-di-p-tolylaminophenyl)cyclohexane
1,1-Bis(4-di-p-tolylaminophenyl)-4-phenylcyclohexane
4,4′-Bis(diphenylamino)quadriphenyl
Bis(4-dimethylamino-2-methylphenyl)-phenylmethane
N,N,N-Tri(p-tolyl)amine
4-(di-p-tolylamino)-4′-[4(di-p-tolylamino)-styryl]stilbene
N,N,N′,N′-Tetra-p-tolyl-4-4′-diaminobiphenyl
N,N,N′,N′-Tetraphenyl-4,4′-diaminobiphenyl
N,N,N′,N′-tetra-1-naphthyl-4,4′-diaminobiphenyl
N,N,N′,N′-tetra-2-naphthyl-4,4′-diaminobiphenyl N-Phenylcarbazole
4,4′-Bis[N-(1-naphthyl)-N-phenylamino]biphenyl
4,4′-Bis[N-(1-naphthyl)-N-(2-naphthyl)amino]biphenyl
4,4″-Bis[N-(1-naphthyl)-N-phenylamino]p-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4″-Bis[N-(1-anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylamino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4″-diamino-p-terphenyl
4,4′-Bis {N-phenyl-N-[4-(1-naphthyl)-phenyl]amino}biphenyl
4,4′-Bis[N-phenyl-N-(2-pyrenyl)amino]biphenyl
2,6-Bis[N,N-di(2-naphthyl)amine]fluorene
1,5-Bis[N-(1-naphthyl)-N-phenylamino]naphthalene
4,4′,4″-tris[(3-methylphenyl)phenyl amino]triphenyl amine
N,N′-bis[4-([1,1′-biphenyl]-4-ylphenylamino)phenyl]-N,N′-di-1-naphthalenyl-[1,1′-Biphenyl]-4,4′-diamine
N,N′-di-1-naphthalenyl-N,N′-bis[4-(1-naphthalenylphenylamino)phenyl]-[1,1′-Biphenyl]-4,4′-diamine
N,N′-bis[4-(di-1-naphthalenylamino)phenyl]-N,N′-di-1-naphthalenyl-[1,1′-Biphenyl]-4,4′-diamine
N,N′-di-1-naphthalenyl-N,N′-bis[4-(2-naphthalenylphenylamino)phenyl]-[1,1′-Biphenyl]-4,4′-diamine
N,N′-bis[4-[(3-methylphenyl)phenylamino]phenyl]-N,N′-diphenyl-[1,1′-Biphenyl]-4,4′-diamine
N,N-bis[4-(diphenylamino)phenyl]-N′,N′-diphenyl-[1,1′-Biphenyl]-4,4′-diamine

Another class of useful hole-transporting materials includes polycyclic aromatic compounds as described in EP 1 009 041. Tertiary aromatic amines with more than two amine groups may be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Electron-Transporting Layer (ETL)

Subject to the limitations of the invention, preferred thin film-forming materials for use in forming the electron-transporting layer 111 of the organic EL devices of this invention are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural formula (E): 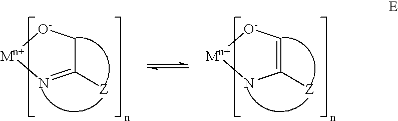
wherein

M represents a metal;

n is an integer of from 1 to 4; and

Z independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; an earth metal, such aluminum or gallium, or a transition metal such as zinc or zirconium. Generally any monovalent, divalent, trivalent, or tetravalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:
CO-1: Aluminum trisoxine [alias, tris(8-quinolinolato)aluminum(III)]
CO-2: Magnesium bisoxine [alias, bis(8-quinolinolato)magnesium(II)]
CO-3: Bis[benzo {f}-8-quinolinolato]zinc (II)
CO-4: Bis(2-methyl-8-quinolinolato)aluminum(III)-μ-oxo-bis(2-methyl-8-quinolinolato)aluminum(III)
CO-5: Indium trisoxine [alias, tris(8-quinolinolato)indium]
CO-6: Aluminum tris(5-methyloxine) [alias, tris(5-methyl-8-quinolinolato)aluminum(III)]
CO-7: Lithium oxine [alias, (8-quinolinolato)lithium(I)]
CO-8: Gallium oxine [alias, tris(8-quinolinolato)gallium(III)]
CO-9: Zirconium oxine [alias, tetra(8-quinolinolato)zirconium(IV)]

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural formula (G) are also useful electron transporting materials: 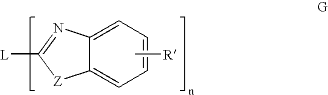
Where:

n is an integer of 3 to 8;

Z is O, NR or S; and
R and R′ are individually hydrogen; alkyl of from 1 to 24 carbon atoms, for example, propyl, t-butyl, heptyl, and the like; aryl or hetero-atom substituted aryl of from 5 to 20 carbon atoms for example phenyl and naphthyl, furyl, thienyl, pyridyl, quinolinyl and other heterocyclic systems; or halo such as chloro, fluoro; or atoms necessary to complete a fused aromatic ring;

L is a linkage unit consisting of alkyl, aryl, substituted alkyl, or substituted aryl, which conjugately or unconjugately connects the multiple benzazoles together. An example of a useful benzazole is 2,2′,2″-(1,3,5-phenylene)tris[1-phenyl-1H-benzimidazole].

Triazines are also known to be useful as electron transporting materials.

Other Useful Organic Layers and Device Architecture

In some instances, layers 109 and 111 can optionally be collapsed into a single layer that serves the function of supporting both light emission and electron transportation. It also known in the art that emitting materials may be included in the hole-transporting layer, which may serve as a host. Multiple materials may be added to one or more layers in order to create a white-emitting OLED, for example, by combining blue- and yellow-emitting materials, cyan- and red-emitting materials, or red-, green-, and blue-emitting materials. White-emitting devices are described, for example, in EP 1 187 235, US 20020025419, EP 1 182 244, U.S. Pat. No. 5,683,823, U.S. Pat. No. 5,503,910, U.S. Pat. No. 5,405,709, and U.S. Pat. No. 5,283,182 and may be equipped with a suitable filter arrangement to produce a color emission.

This invention may be used in so-called stacked device architecture, for example, as taught in U.S. Pat. No. 5,703,436 and U.S. Pat. No. 6,337,492.

Deposition of Organic Layers

The organic materials mentioned above are suitably deposited by any means suitable for the form of the organic materials. In the case of small molecules, they are conveniently deposited through sublimation, but can be deposited by other means such as from a solvent with an optional binder to improve film formation. If the material is a polymer, solvent deposition is usually preferred. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. No. 5,688,551, U.S. Pat. No. 5,851,709 and U.S. Pat. No. 6,066,357) and inkjet method (U.S. Pat. No. 6,066,357).

One preferred method for depositing the materials of the present invention is described in US 2004/0255857 and U.S. Ser. No. 10/945,941 where different source evaporators are used to evaporate each of the materials of the present invention. A second preferred method involves the use of flash evaporation where materials are metered along a material feed path in which the material feed path is temperature controlled. Such a preferred method is described in the following co-assigned patent applications: U.S. Ser. No. 10/784,585; U.S. Ser. No. 10/805,980; U.S. Ser. No. 10/945,940; U.S. Ser. No. 10/945,941; U.S. Ser. No. 11/050,924; and U.S. Ser. No. 11/050,934. Using this second method, each material may be evaporated using different source evaporators or the solid materials may be mixed prior to evaporation using the same source evaporator.

Encapsulation

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

Optical Optimization

OLED devices of this invention can employ various well-known optical effects in order to enhance its properties if desired. This includes optimizing layer thicknesses to yield maximum light transmission, providing dielectric mirror structures, replacing reflective electrodes with light-absorbing electrodes, providing anti glare or anti-reflection coatings over the display, providing a polarizing medium over the display, or providing colored, neutral density, or color conversion filters over the display. Filters, polarizers, and anti-glare or anti-reflection coatings may be specifically provided over the cover or as part of the cover.

### EXAMPLES

### Device Example 1

An EL device (Example 1) was constructed in the following manner:
1. A glass substrate coated with an 21.5 nm layer of indium-tin oxide (ITO) as the anode was sequentially ultrasonicated in a commercial detergent, rinsed in deionized water, degreased in toluene vapor and exposed to oxygen plasma for about 1 min.
2. Over the ITO was deposited a 1 nm fluorocarbon (CFx) hole-injecting layer (HIL) by plasma-assisted deposition of CHF₃.
3. A hole-transporting layer (HTL) of N,N′-di-1-naphthyl-N,N′-diphenyl-4,4′-diaminobiphenyl (NPB) having a thickness of 75 nm was then evaporated from a quartz boat.
4. A 20 nm light-emitting layer (LEL), including host material Inv-3 and light-emitting material L53 (1.5 vol %), was then deposited onto the hole-transporting layer. These materials were also evaporated from quartz boats.
5. A 35 nm electron-transporting layer (ETL) of tris(8-quinolinolato)aluminum (III) (AlQ₃) was then deposited onto the light-emitting layer. This material was also evaporated from a quartz boat.
6. On top of the AlQ₃ layer was deposited 0.5 nm of LiF followed by 100 nm cathode formed of Al.

The above sequence completed the deposition of the EL device. The device was then hermetically packaged in a dry glove box for protection against ambient environment. The devices thus formed were tested for operational voltage and color at an operating current of 20 mA/cm² and the results are reported in Table 1 and Table 2 in the form of voltage (V) and CIE (Commission Internationale de L'Eclairage) coordinates.

### Device Example 2

An EL device (Example 2) satisfying the requirements of the invention, was fabricated in an identical manner as Sample 1, except ETM-2 and lithium were used in a 98:2 volume ratio instead of AlQ₃.

### Device Example 3

An EL device (Example 3) satisfying the requirements of the invention, was fabricated in an identical manner as Sample 1, except AlQ₃ and ETM-4 were used in a 1:3 volume ratio instead of AlQ₃.

### Device Example 4

An EL device (Example 4) satisfying the requirements of the invention, was fabricated in an identical manner as Sample 1, except ETM-6 was used instead of AlQ₃.

TABLE 1

| | | | | Voltage | |
|---|---|---|---|---|---|
| Example | ETL | CIEx | CIEy | (V) | Type |
| 1 | AlQ₃ | 0.16 | 0.17 | 7.5 | Comparison |
| 2 | ETM-2/Li | 0.14 | 0.14 | 4.4 | Invention |
| 3 | AlQ₃/ETM-4 | 0.17 | 0.15 | 6.0 | Invention |
| 4 | ETM-6 | 0.14 | 0.13 | 9.4 | Invention |

Comparison example 1 uses only AlQ₃ in the ETL. The Invention Examples 2-4 use ETLs that employ only a minor portion or no AlQ₃ and exhibit improved emission color with less undesirable green emission. Operational voltage is improved in Examples 2 and 3.

### Device Example 5

A comparative EL device (Example 5) was fabricated in an identical manner as Example 1, except the light-emitting layer was 40 nm thick, and the electron transporting-layer was 15 nm thick.

### Device Example 6

An EL device (Example 6) satisfying the requirements of the invention was fabricated in an identical manner as Example 5, except ETM-2 and lithium were used in a 98:2 volume ratio instead of AlQ₃.

### Device Example 7

An EL device (Example 7) satisfying the requirements of the invention was fabricated in an identical manner as Example 5, except AlQ₃ and ETM-4 were used in a 1:3 volume ratio instead of AlQ₃.

### Device Example 8

An EL device (Example 8) satisfying the requirements of the invention was fabricated in an identical manner as Example 5, except ETM-6 was used instead of AlQ₃.

TABLE 2

| | | | | Voltage | |
|---|---|---|---|---|---|
| Example | ETL | CIEx | CIEy | (V) | Type |
| 5 | AlQ₃ | 0.14 | 0.14 | 8.0 | Comparison |
| 6 | ETM-2/Li | 0.14 | 0.14 | 5.6 | Invention |
| 7 | AlQ₃/ETM-4 | 0.14 | 0.13 | 6.6 | Invention |
| 8 | ETM-6 | 0.14 | 0.13 | 8.6 | Invention |

Comparison Example 5 uses AlQ₃ in the ETL. The device layer thicknesses are different than those in comparison Example 1. The invention Examples 6-8 use an ETL that only only a minor portion or no AlQ₃ and exhibit improved emission color with less undesirable green emission. Operational voltage is improved in Examples 6 and 7.

The entire contents of the patents and other publications referred to in this specification are incorporated herein by reference. The invention has been described in detail with particular reference to certain preferred embodiments thereof, but it will be understood that variations and modifications can be effected within the spirit and scope of the invention.

### Parts List

101 Substrate
103 Anode
105 Hole-Injecting layer (HIL)
107 Hole-Transporting layer (HTL)
109 Light-Emitting layer (LEL)
111 Electron-Transporting layer (ETL)
113 Cathode
150 Current/Voltage source
160 Electrical conductors

1. An OLED device comprising a cathode, an anode, and having therebetween a light emitting layer containing
(a) an anthracene material represented by Formula (1): 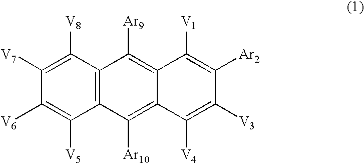
wherein:
Ar₂, Ar₉, and Ar₁₀ independently represent an aryl group,
v₁, v₃, v₄, v₅, v₆, v₇, and v₈ independently represent hydrogen or a substituent; and
(b) a light emitting dopant;
the device further containing on the cathode side of the light emitting layer an electron transporting layer that contains a minor portion or no AlQ₃.

2. An OLED device of claim 1 wherein the electron transporting layer contains substantially no AlQ₃.

3. An OLED device of claim 1 wherein the electron transporting layer is adjacent to the light emitting layer.

4. An OLED device of claim 1 wherein the electron transporting layer is substantially free of a material capable of emitting green light when in an emitting layer.

5. The OLED device of claim 1, wherein Ar₉ and Ar₁₀ are naphthalene.

6. The OLED device of claim 1, wherein the anthracene material is represented by:

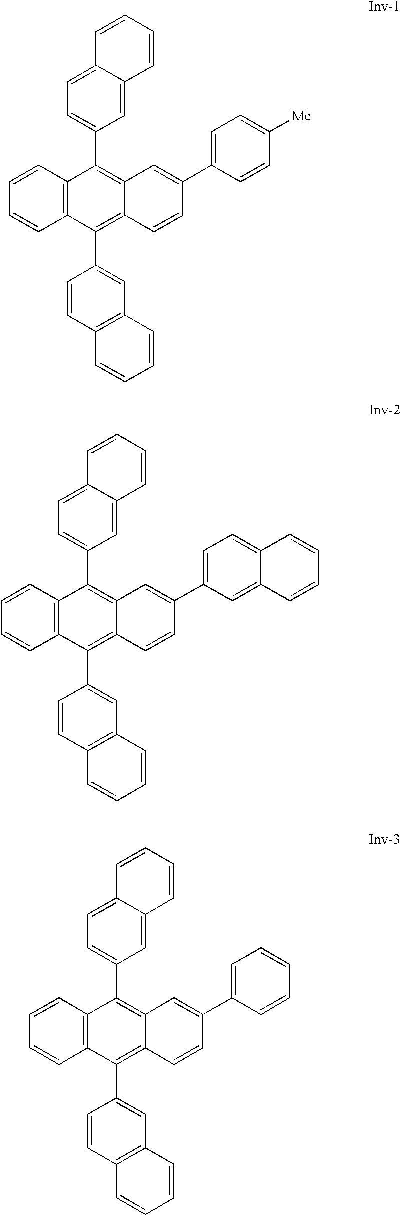

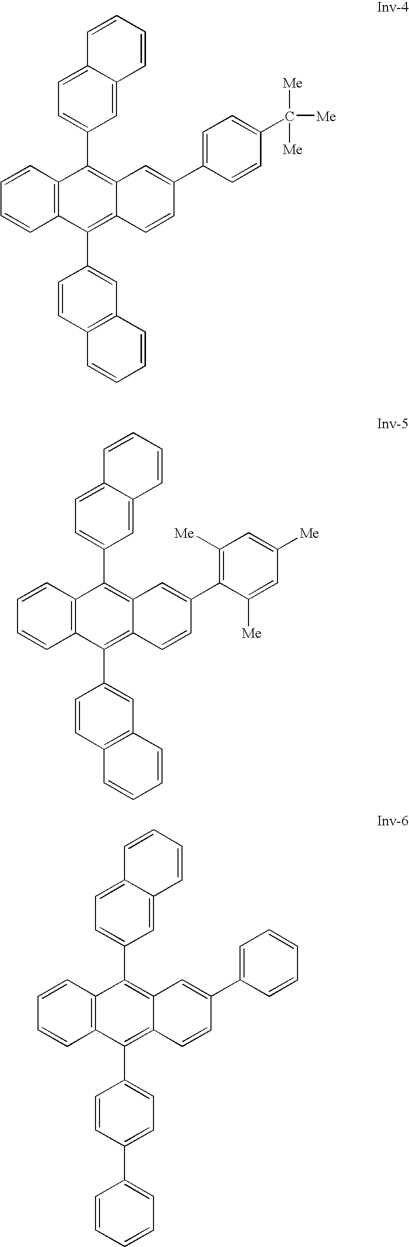

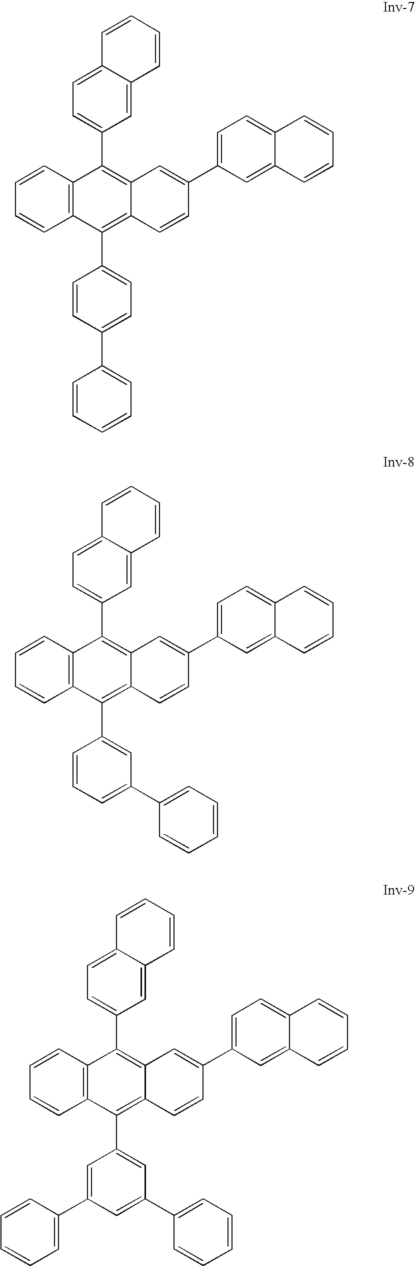

7. The OLED device of claim 1, wherein the light emitting dopant is represented by Formula (2): 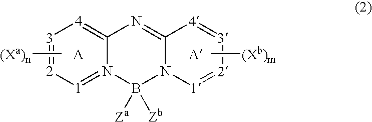
wherein
A and A′ represent independent azine ring systems corresponding to 6-membered aromatic ring systems containing at least one nitrogen;
each X^{a} and X^{b} is an independently selected substituent, two of which may join to form a fused ring to A or A′;
m and n are independently 0 to 4;
Z^{a} and Z^{b} are independently selected substituents; and
1, 2, 3, 4, 1′, 2′, 3′, and 4′ are independently selected as either carbon or nitrogen atoms.

8. The OLED device of claim 1, wherein the material comprising the electron transporting layer is represented by Formula (3): 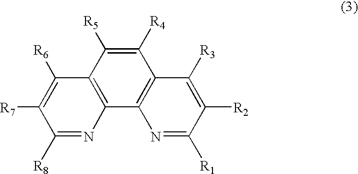
wherein:
R₁-R₈ are independently hydrogen, alkyl, aryl or substituted aryl, and at least one of R₁-R₈ is aryl or substituted aryl.

9. The OLED device of claim 8, wherein the material comprising the electron transporting layer comprises 2 phenanthroline ring groups.

10. The OLED device of claim 8, wherein the material comprising the electron transporting layer is selected from the group consisting of:

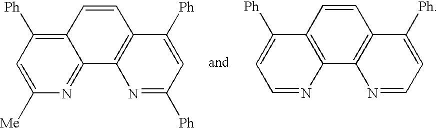

11. The OLED device of claim 8, wherein the electron transporting layer also comprises lithium.

12. The OLED device of claim 1, wherein the material comprising the electron transporting layer is represented by Formula (4), 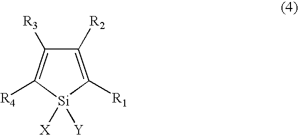
wherein:
R₁ to R₄ are independently hydrogen, alkyl, aryl, or heteroaryl groups;
X and Y are independently hydrogen, alkyl, aryl, or heteroaryl groups, and may be bonded together to form a saturated or unsaturated ring.

13. The OLED device of claim 12, wherein both R₁ and R₄ comprise a 5 or 6 membered ring containing a nitrogen atom.

14. The OLED device of claim 1, wherein the material comprising the electron transporting layer is represented by Formula (6), 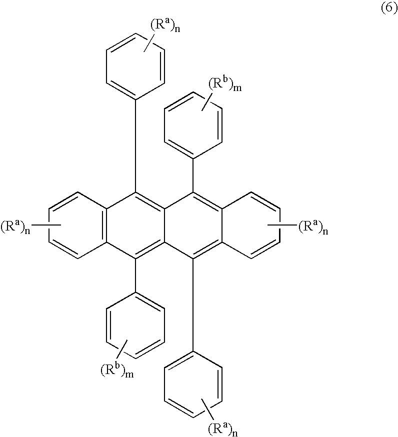
wherein:
R^{a} and R^{b} are substituent groups;
n is selected from 0-4; and
m is selected from 0-5.

15. The OLED device of claim 14, wherein the material comprising the electron transporting layer is represented by Formula (7) or (8), 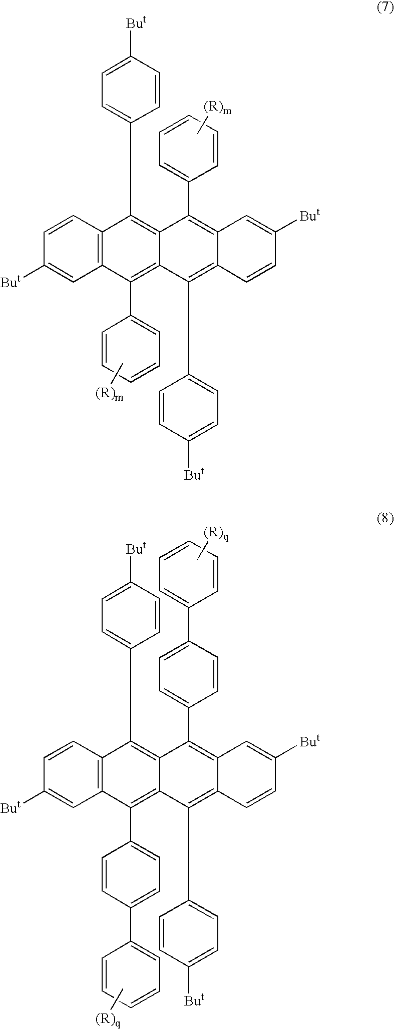
wherein:
R are substituent groups;
m is selected from 0-5; and
q is selected from 0-5.

16. The OLED device of claim 1, wherein the material comprising the electron transporting layer is represented by Formula (12), 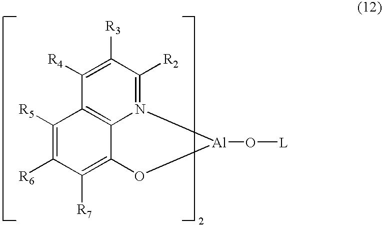
wherein:
R₂ represents an electron donating group,
R₃ and R₄ each independently represent hydrogen or an electron donating group,
R₅, R₆, and R₇ each independently represent hydrogen or an electron accepting group, and
L is an aromatic moiety linked to the aluminum by oxygen which may be substituted such that L has from 7 to 24 carbon atoms.

17. An OLED device comprising a cathode, an anode, and having therebetween a light emitting layer containing an 2,9,10-tri aryl substituted anthracene compound and containing on the cathode side of the light emitting layer an electron transporting layer that comprises one or more compounds selected from: 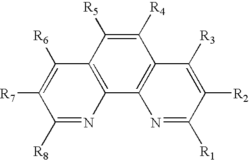
wherein:
R₁-R₈ are independently hydrogen, alkyl, aryl or substituted aryl, and at least one of R₁-R₈ is aryl or substituted aryl; or 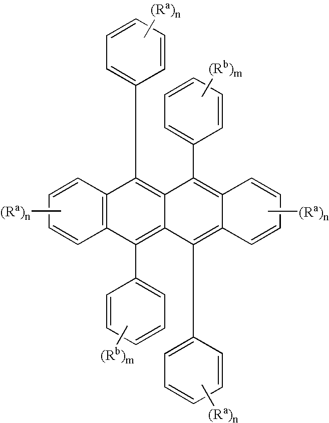
wherein:
R^{a} and R^{b} are substituent groups;
n is selected from 0-4; and
m is selected from 0-5.

18. An OLED device of claim 17, wherein the anthracene material is represented by Formula (14), 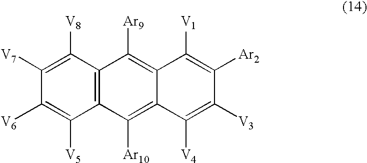
wherein:
Ar₂ represent an aryl group,
Ar₉, and Ar₁₀ independently represent a naphthalene group, and
v₁, v₃, v₄, v₅, v₆, v₇, and v₈ independently represent hydrogen or a substituent.

19. An OLED device of claim 17, wherein the material comprising the electron transporting layer is selected from the group consisting of:

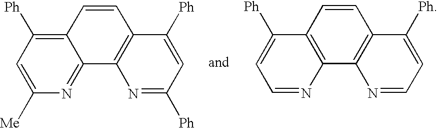

20. The OLED device of claim 17, wherein the material comprising the electron transporting layer is selected from a group consisting of Formula (15) and (16), 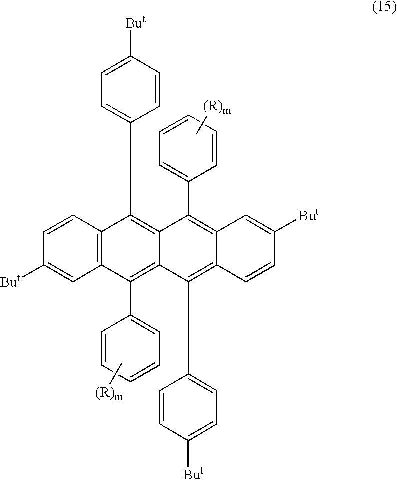 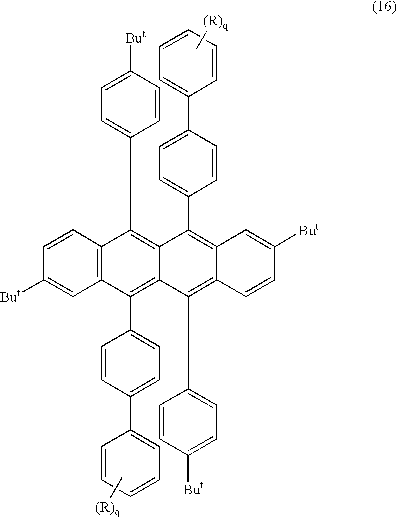
wherein:
R are substituent groups;
m is selected from 0-5; and
q is selected from 0-5.
